(19) United States
(12) Patent Application Publication
(10) Pub. No.: US 2013/0269744 A1
(43) Pub. Date: Oct. 17, 2013

(54) THERMOELECTRIC CONVERSION MODULE

(71) Applicant: PANASONIC CORPORATION, Osaka (JP)

(72) Inventors: Satoshi Maeshima, Hyogo (JP); Kaori Toyoda, Hyogo (JP); Takaaki Higashida, Osaka (JP); Takashi Kubo, Osaka (JP)

(73) Assignee: PANASONIC CORPORATION, Osaka (JP)

(21) Appl. No.: 13/860,142

(22) Filed: Apr. 10, 2013

(30) Foreign Application Priority Data
Apr. 11, 2012 (JP) 2012-089940
Mar. 5, 2013 (JP) 2013-043122

(51) Int. Cl. H01L 35/32

(52) U.S. Cl. CPC H01L 35/32
USPC 136/212; 136/205

(57) ABSTRACT

An object of the invention is to provide a thermoelectric conversion element and a thermoelectric conversion module in which high-density arrangement is easy, and thus connection reliability is high, and a manufacturing method thereof. There is provided a thermoelectric conversion element including a tube, a thermoelectric conversion material with which the tube is filled, and a plated metal layer that is plated on one end or both ends of the thermoelectric conversion material. The thermoelectric conversion material protrudes from the tube, and the plated metal layer covers a protruding portion of the thermoelectric conversion material. Furthermore, there is provided a thermoelectric conversion module that is obtained by connecting a plurality of thermoelectric conversion elements in series.

### CROSS REFERENCE TO RELATED APPLICATIONS

This application is entitled to the benefits of Japanese patent application No. 2012-089940, filed Apr. 11, 2012 and Japanese Patent application No. 2013-043122, filed Mar. 5, 2013, the entire of which are incorporated by reference herein.

### TECHNICAL FIELD

The present invention relates to a thermoelectric conversion module.

### BACKGROUND ART

The thermoelectric conversion module includes a P-type thermoelectric element and an N-type thermoelectric conversion element that are connected in series. The thermoelectric element has been developed as a power generation element using a Seebeck effect. For example, a power generation system using industrial waste heat has been made, but problems such as low thermoelectric conversion efficiency and high power generation cost have been pointed out.

An example of a thermoelectric conversion module including the thermoelectric element is shown in FIG. 1 (refer to PTL 1). In thermoelectric conversion module 100 shown in FIG. 1, P-type thermoelectric conversion element 50 and N-type thermoelectric conversion element 60 are connected in series through a bonding electrode (electrical wiring) 70, whereby a plurality of PN element pairs are formed. Ceramic substrate 80 is disposed on one end surfaces of the PN element pairs, and ceramic substrate 90 is disposed on the other end surfaces of the PN element pairs. Power generation is carried out by heating ceramic substrate 80 and cooling (not heating) the other ceramic substrate 90 of the element pairs. Arrows in FIG. 1 indicate heat flow due to heating and cooling. Electricity that is generated is taken out through a pair of current introduction terminals 15 and 15′.

In addition, a method of manufacturing a thermoelectric conversion module to be described below is suggested (refer to PTL 2). As shown in FIG. 2, P-type thermoelectric conversion material 150 and N-type thermoelectric conversion Material 160 are inserted inside honeycomb mold 110, and are impregnated with insulating resin 120, whereby block 130, which is integrated as a whole, is molded. Next, block 130 is cut by cutter 140 in a direction orthogonal to a longitudinal direction of each element for a predetermined thickness, whereby block pieces 130′ is obtained. In block piece 130′, P-type thermoelectric conversion element 151 and N-type thermoelectric conversion element 161 are alternately arranged. When plating is performed in such a manner that P-type thermoelectric conversion element 151 and N-type thermoelectric conversion element 161 are connected in series, a thermoelectric conversion module is obtained.

In the thermoelectric conversion module that is obtained in this manner, since P-type thermoelectric conversion material 150 and N-type thermoelectric conversion material 160 are covered with insulating resin 120, short-circuit between thermoelectric conversion elements are reliably prevented. Accordingly, a thermoelectric conversion module in which P-type thermoelectric conversion element 151 and N-type thermoelectric conversion element 161 are arranged with high density may be obtained.

A thermoelectric conversion module, in which thermoelectric conversion elements including a thermoelectric conversion material and a resin film covering a side surface of the thermoelectric conversion material are arranged, is also suggested (PTL 3). In addition, other several suggestions for making the thermoelectric conversion elements in the thermoelectric conversion module highly dense are also made (PTL 4 or PTL 5).

Furthermore, a suggestion for increasing productivity of the thermoelectric conversion module is also made. In PTL 3, when connecting an thermoelectric conversion element to an electrical wiring (electrode), a lattice-shaped jig is used, and dimensions of the lattice-shaped jig is set to be within 100.5% with respect to dimensions of the thermoelectric conversion element to reduce a variation in a connection position (PTL 6). In PTL 4, the width of an electrical wiring (electrode) that connects thermoelectric conversion elements that are located at ends of a thermoelectric conversion module is set to be smaller than the width of other electrical wirings to remove a positional deviation of thermoelectric conversion elements (PTL 7).

Furthermore, in an thermoelectric conversion apparatus, an electrical wiring (electrode), which is connected to a thermoelectric conversion element, is disposed in a groove patterned in a substrate to miniaturize the electrical wiring and reduce electrical resistance of the electrical wiring (PTL 8).

As one use of the thermoelectric conversion module, an optical module in which an optical element and a thermoelectric semiconductor are provided is also suggested (PTL 9 and PTL 10).

### CITATION LIST

### Patent Literature

PTL 1: Japanese Patent No. 3958857
PTL 2: Japanese Patent Application Laid-Open No. 2009-76603
PTL 3: U.S. Pat. No. 6,252,154
PTL 4: US Patent Application Laid-Open No. 2003/0057560
PTL 5: US Patent Application Laid-Open No. 2006/0180191
PTL 6: Japanese Patent Application Laid-Open No. 2003-347605
PTL 7: Japanese Patent Application Laid-Open No. 2004-228230
PTL 8: Japanese Patent Application Laid-Open No. 2009-43808
PTL 9: Japanese Patent Application Laid-Open No. 2003-198042
PTL 10: US Patent Application Laid-Open No. 2003/0127661

### SUMMARY OF INVENTION

### Technical Problem

The thermoelectric conversion module is an apparatus that carries out power generation by exposing one end (refer to ceramic substrate 80 in FIG. 1) to a high temperature, and by exposing the other end (refer to ceramic substrate 90 in FIG. 1) to a low temperature. In this manner, since the thermoelectric conversion module is used for a long period of time in a state in which a difference in temperature is present, due to a difference in thermal expansion caused by the difference in temperature, there is a tendency for thermal stress to occur at a bonding portion between the thermoelectric conversion element and a wiring portion (refer to bonding electrode 70 in FIG. 1). When the thermal stress at the bonding portion between the thermoelectric conversion element and the wiring portion increases, there is a concern for occurrence of cracking at the bonding portion, and thus bonding reliability decreases. As a result, reliability of the thermoelectric conversion module itself decreases.

The invention has been made to accomplish the problem in the related art, and an object thereof is to provide a thermoelectric conversion element and a thermoelectric conversion module with high connection reliability.

### Solution to Problem

The invention relates to a thermoelectric conversion element and a thermoelectric conversion module to be described below.

[1] According to an aspect of the invention, there is provided a thermoelectric conversion module including: two or more P-type thermoelectric conversion elements that include a P-type thermoelectric conversion material; two or more N-type thermoelectric conversion elements that include an N-type thermoelectric conversion material; and an electrical wiring that connects each of the P-type thermoelectric conversion elements with each of the N-type thermoelectric conversion elements in series.

The electrical wiring is solder-bonded to a longitudinal end surface of the P-type thermoelectric conversion material and the N-type thermoelectric conversion material, a width of the electric wiring is narrower than a width of the P-type thermoelectric conversion material and the N-type thermoelectric conversion material, the electrical wiring is located at a central portion in the width direction of the end surface, and a solder that bonds each of the end surfaces and the electrical wiring has a fillet shape.

[2] In the thermoelectric conversion module according to [1], the two or more P-type thermoelectric conversion elements, and the two or more N-type thermoelectric conversion elements including the N-type thermoelectric conversion material may be arranged along a plurality of rows.

[3] In the thermoelectric conversion module according to [1] or [2], a contact angle of the solder that solder-bonds the electrical wiring with respect to the end surfaces of the P-type thermoelectric conversion element or the N-type thermoelectric conversion element may be 75° or less.

[4] The thermoelectric conversion module according to any one of [1] to [3], the P-type thermoelectric conversion element may include a plated metal layer that covers the longitudinal end surfaces of the P-type thermoelectric conversion material, the electrical wiring may be solder-bonded to the P-type thermoelectric conversion material through the plated metal layer, the N-type thermoelectric conversion element may include a plated metal layer that covers the longitudinal end surfaces of the N-type thermoelectric conversion material, and the electrical wiring may solder-bonded to the N-type thermoelectric conversion material through the plated metal layer.

In the thermoelectric conversion module according to any one of [1] to [4], the P-type thermoelectric conversion element may further include an insulating tube which is filled with the P-type thermoelectric conversion material, and the N-type thermoelectric conversion element may further include an insulating tube which is filled with the N-type thermoelectric conversion material.

### Advantageous Effects of Invention

In the thermoelectric conversion module of the invention, since the width of the wiring that is solder-bonded to the thermoelectric conversion element is appropriately adjusted, a shape of the solder is optimized, and strength of solder-bonding between the thermoelectric conversion element and the electrical wiring plate increases. As a result, mounting reliability increases. In addition, since the width of the wiring that is solder-bonded to the thermoelectric conversion element is appropriately adjusted, arrangement density of the thermoelectric conversion element may be increased.

More preferably, in the thermoelectric conversion element of the thermoelectric conversion module of the invention, since the thermoelectric conversion material with which the insulating tube is filled, a short-circuit between thermoelectric conversion elements are reliably suppressed. Accordingly, the thermoelectric conversion elements may be arranged in a close contact state, and thus a thermoelectric conversion module in which the thermoelectric conversion elements are arranged with high density may be obtained.

### BRIEF DESCRIPTION OF DRAWINGS

FIG. 1 is a diagram illustrating an example of a thermoelectric conversion module in the related art;

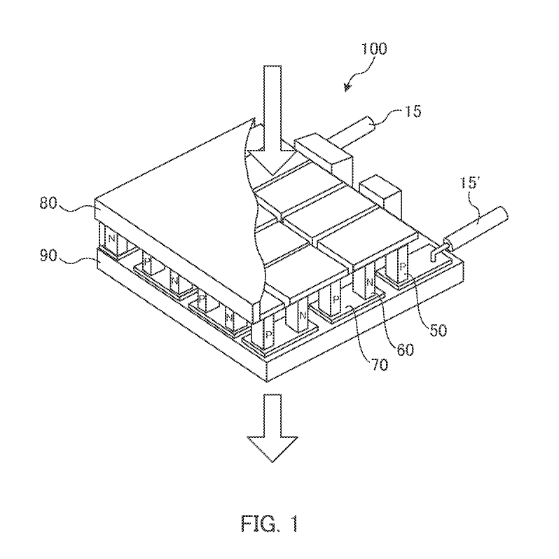

FIG. 2 is a diagram illustrating an example of a manufacturing flow of the thermoelectric conversion module in the related art;

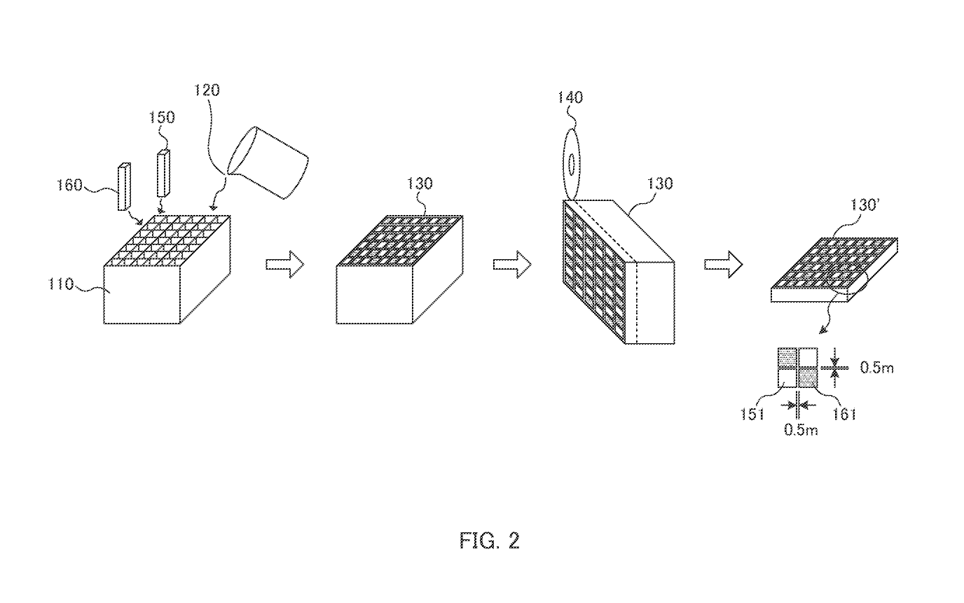

FIG. 3 is a diagram illustrating an arrangement state of a P-type thermoelectric conversion element and an N-type thermoelectric conversion element in a thermoelectric conversion module;

FIGS. 4A and 4B are cross-sectional diagrams of the thermoelectric conversion element, respectively;

FIGS. 5A and 5B are cross-sectional diagrams of the thermoelectric conversion module, respectively;

FIGS. 6A and 6B are cross-sectional diagrams of a bonding portion of the thermoelectric conversion element that is solder-bonded to an electrical wiring plate in the thermoelectric conversion module, respectively;

FIGS. 7A and 7B are cross-sectional diagrams of a bonding portion of the thermoelectric conversion element that is solder-bonded to a wiring constituted by an electrical wire in the thermoelectric conversion module, respectively;

FIG. 8 is a diagram schematically illustrating a bonding portion between the thermoelectric conversion element and the electrical wiring of the electrical wiring plate in the thermoelectric conversion module; and

FIG. 9 is a cross-sectional diagram of the bonding portion of the thermoelectric conversion element that is solder-bonded to the electric wiring plate in the thermoelectric conversion module.

### DESCRIPTION OF EMBODIMENTS

A thermoelectric conversion module of the invention includes two or more P-type thermoelectric conversion elements, two or more N-type thermoelectric conversion elements, and an electric wiring that connects these in series. The P-type thermoelectric conversion elements and the N-type thermoelectric conversion elements are alternately connected in series by the electrical wiring.

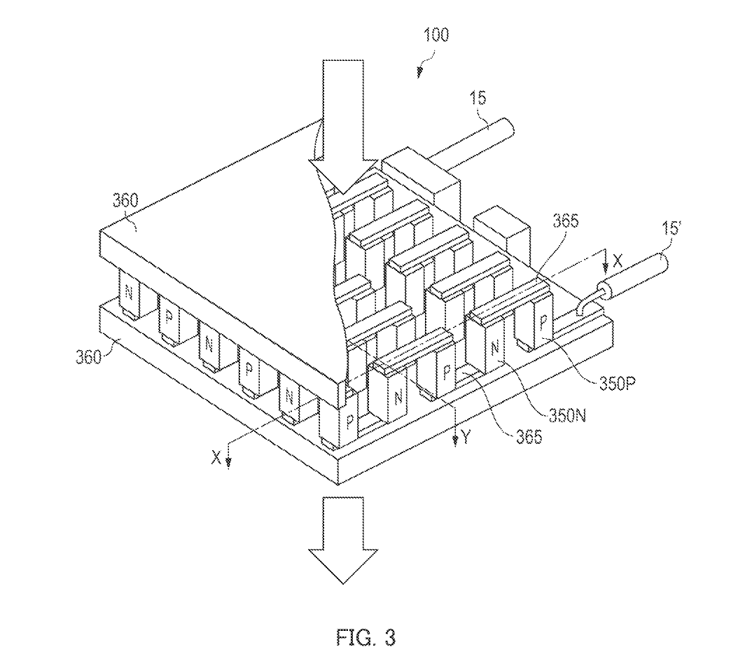

FIG. 3 illustrates an example of an arrangement state of P-type thermoelectric conversion elements 350P and N-type thermoelectric conversion elements 350N in thermoelectric conversion module 100. It is preferable that P-type thermoelectric conversion elements 350P and N-type thermoelectric conversion elements 350N be disposed in a matrix arrangement. More preferably, P-type thermoelectric conversion elements 350P and N-type thermoelectric conversion elements 350N are arranged along a plurality of rows, and still more preferably three or more rows. Electrical wirings 365 are solder-bonded to both longitudinal end surfaces of each of P-type thermoelectric conversion elements 350P and N-type thermoelectric conversion elements 350N. In FIG. 3, P-type electric conversion element 350P and N-type thermoelectric conversion element 350N are electrically connected in series. Electrical wiring 365 is disposed in electrical wiring plate 360, but electrical wiring plate 360 is a member having an arbitrary configuration.

The P-type thermoelectric conversion element and the N-type thermoelectric conversion element contain at least a thermoelectric conversion material, respectively. A thermoelectric conversion element in which a thermoelectric conversion material is doped in a P-type is referred to as a P-type thermoelectric conversion element, and a thermoelectric conversion element in which a thermoelectric conversion material is doped in an N-type is referred to as an N-type thermoelectric conversion element.

The thermoelectric conversion material in the P-type thermoelectric conversion element and the N-type thermoelectric conversion element is a material that causes electromotive force to occur when a difference in temperature is given thereto. The thermoelectric conversion material may be selected according to a difference in temperature that occurs during use. As an example of the thermoelectric conversion material, in a case where the difference in temperature is room temperature to 500 K, a bismuth-tellurium-based (Bi—Te based) material is preferable, in a case where the difference in temperature is room temperature to 800 K, a lead-tellurium-based (Pb—Te-based) material is preferable, in a case where the difference in temperature is room temperature to 1,000 K, a silicon-germanium-based (Si—Ge-based) material is preferable. Examples of the thermoelectric conversion material having excellent performance near room temperature include a Bi—Te-based material.

Doping of the thermoelectric conversion material is carried out by adding a dopant to the thermoelectric conversion material. Examples of a p-type dopant include Sb, and examples of an n-type dopant include Se. The thermoelectric conversion material forms a mixed crystal due to the addition of this dopant. Accordingly, the dopant is contained in the thermoelectric conversion material, for example, with an amount in a degree expressed in a compositional formula of the material such as “Bi_{0.5}Sb_{1.5}Te₃” and “Bi₂Te_{2.7}Se_{0.3}”.

The thermoelectric conversion material in the P-type thermoelectric conversion element and the N-type thermoelectric conversion element can be a material with which an insulating tube is filled. The insulating tube which is filled with the thermoelectric conversion material is preferably molded from a heat resistant insulating material. Examples of the heat resistant material include heat resistant organic resins, and preferred examples include heat resistant glass (material that is a kind of borosilicate glass obtained by mixing SiO₂ and B₂O₃ and has a coefficient of thermal expansion of approximately 3×10⁻⁶/K), and the like. Both ends of the tube in the thermoelectric conversion element are opened. Although not particularly limited, an inner diameter and an outer diameter of the tube in the thermoelectric conversion element may be 1.8 mm and 3 mm, respectively.

In the thermoelectric conversion material of the P-type thermoelectric conversion element and the N-type thermoelectric conversion element, it is preferable that an end surface or both end surfaces thereof in a longitudinal direction be coated with a plated metal layer. It is preferable that the plated metal layer be a metal with high wettability with respect to solder, or a metal having a property (barrier characteristic) of suppressing diffusion of a solder component to the thermoelectric conversion material. Although not particularly limited, it is preferable that a kind of a plated metal be nickel plating, molybdenum plating, or the like.

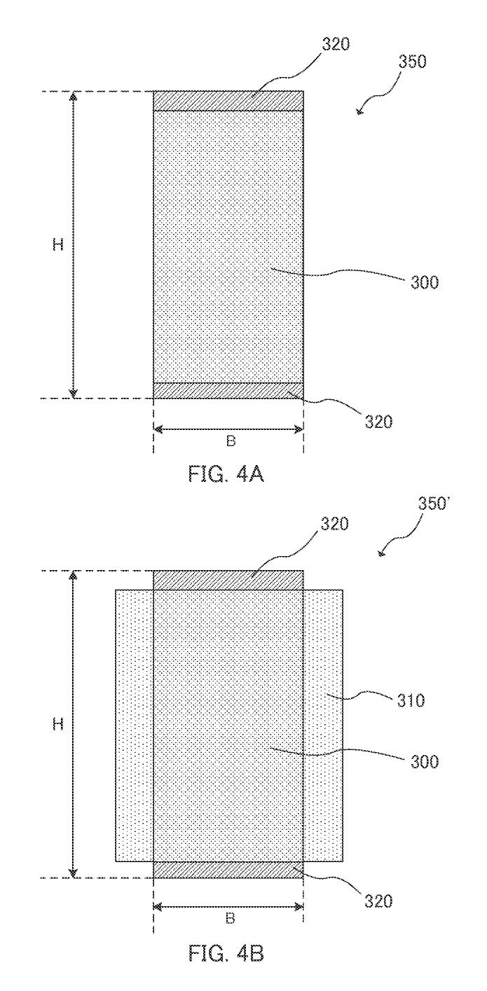

FIG. 4A shows a cross-sectional diagram of Example 1 of the thermoelectric conversion element, and FIG. 4B shows a cross-sectional diagram of Example 2 of the thermoelectric conversion element. Thermoelectric conversion element 350 shown in FIG. 4A includes thermoelectric conversion material 300, and plated metal layer 320 that is formed on both longitudinal ends of thermoelectric conversion material 300. Thermoelectric conversion element 350′ shown in FIG. 4B includes thermoelectric conversion material 300, tube 310 which is filled with thermoelectric conversion material 300, and plated metal layer 320 formed on both ends of thermoelectric conversion material 300.

In thermoelectric conversion element 350′ shown in FIG. 4B, the longitudinal ends of thermoelectric conversion material 300 with which tube 310 is filled may protrude from one opening end of the tube or both opening ends of the tube (preferably, from both opening ends). In a case where thermoelectric conversion material 300 protrudes from tube 310, it is preferable that a protruding portion be covered with plated metal layer 320.

It is preferable that height H (refer to FIGS. 4A and 4B) of thermoelectric conversion element 350 be 1.0 to 3.0 mm, and more preferably 1.0 to 2.0 mm. Width B of the thermoelectric conversion material in thermoelectric conversion element 350 is, for example, 1.8 mm. However, this size is not particularly limited.

In thermoelectric conversion elements 350 and 350′, a contact surface of thermoelectric conversion material 300 with plated metal layer 320 may be roughened. Due to this roughening, adhesiveness between thermoelectric conversion material 300 and plated metal layer 320 can be increased.

A method of manufacturing thermoelectric conversion element 350 shown in FIG. 4A is not particularly limited, but 1) a single crystal or a polycrystal of the thermoelectric conversion material is sliced and processed into thermoelectric conversion material 300, or powders of a thermoelectric conversion material are sintered and processed into thermoelectric conversion material 300, then 2) plated metal layer 320 is formed on both ends of thermoelectric conversion material 300. A plating method is not particularly limited.

A method of manufacturing thermoelectric conversion element 350′ shown in FIG. 4B is not particularly limited. However, for example, thermoelectric conversion element 350′ may be manufactured by a step of 1) filling tube 310 with a thermoelectric conversion material and 2) forming plated metal layer 320 on exposed portions of thermoelectric conversion material 300 that is exposed at the end of tube 310. A plating method is not particularly limited.

1) When filling tube 310 with the thermoelectric conversion material, for example, powders of the thermoelectric conversion material, and tube 310 which is filled with the powders of the thermoelectric conversion material is heated so as to melt and liquefy the thermoelectric conversion material. The melting of the thermoelectric conversion material may be carried out by putting tube 310 in a heating furnace or tube 310 may be heated by a heater. When tube 310 is sequentially heated from one end toward the other end, it is easy to arrange a crystal orientation of the thermoelectric conversion material in one direction, and thus it is easy to increase power generation efficiency of the thermoelectric conversion element. In addition, 1) when filling tube 310 with the thermoelectric conversion material, for example, an end of the tube may be immersed the thermoelectric conversion material that is melt, and the pressure inside the tube is reduced to suction the thermoelectric conversion material.

In a case where the length of tube 310 which is filled with thermoelectric conversion material 300 is long, tube 310 may be cut into individual pieces in a direction orthogonal to the longitudinal direction. Each of the individual pieces is used as the thermoelectric conversion element. In addition, thermoelectric conversion material 300 may be made to protrude from tube 310 by removing an end of tube 310 which is filled with thermoelectric conversion material 300.

The thermoelectric conversion module includes an electrical wiring that electrically connects the P-type thermoelectric conversion element and the N-type thermoelectric conversion element in series. The electrical wiring can be an electrical wire, or an interconnection that is printed on an electrical wiring substrate. The electrical wiring substrate may be, for example, a ceramic substrate (for example, aluminum oxide) having high thermal conductivity or a flexible resin substrate. The printed wiring is, for example, a copper wiring.

When connecting the thermoelectric conversion element to the electrical wiring, both ends of the thermoelectric conversion material of the thermoelectric conversion element may be solder-bonded to the wiring. Preferably, the thermoelectric conversion element may be solder-bonded to the wiring through a plated metal layer formed on both ends of the thermoelectric conversion material of the thermoelectric conversion element.

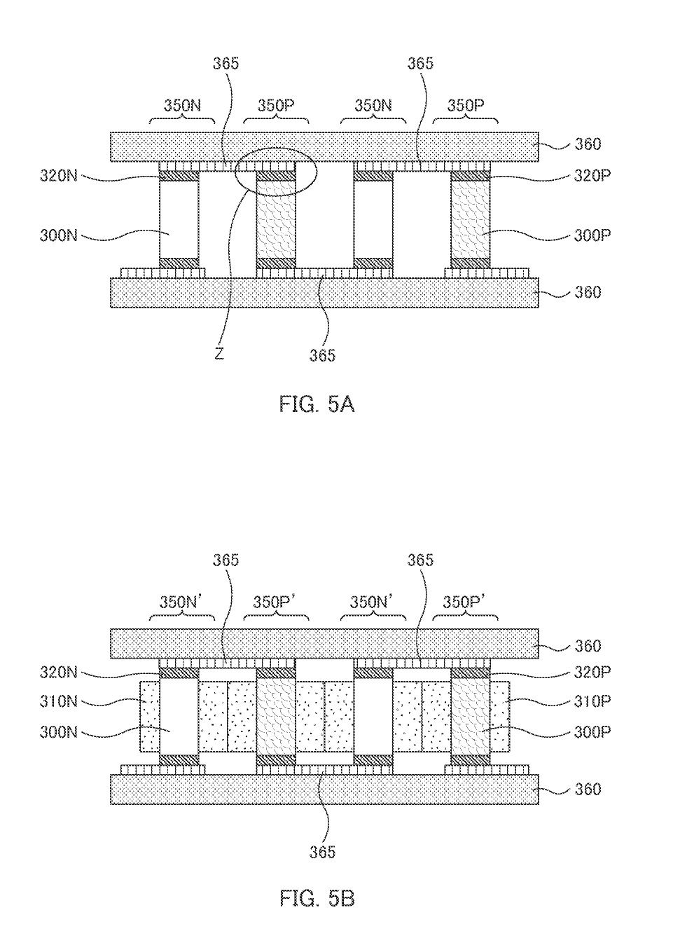

FIGS. 5A and 5B show a cut-surface of the thermoelectric conversion module when being cut along the longitudinal direction of the thermoelectric conversion element (a cross-sectional diagram along a line X-X in FIG. 3, that is, a cross-sectional diagram along an electrical connection direction between thermoelectric conversion elements). The thermoelectric conversion module shown in FIG. 5A includes P-type thermoelectric conversion element 350P and N-type thermoelectric conversion element 350N. P-type thermoelectric conversion element 350P includes P-type thermoelectric conversion material 300P and plated metal layers 320P that are formed on both ends of P-type thermoelectric conversion material 300P. Similarly, N-type thermoelectric conversion element 350N includes N-type thermoelectric conversion material 300N, and plated metal layers 320N that are formed on both ends of N-type thermoelectric conversion material 300N. That is, thermoelectric conversion element 350 shown in FIG. 4A is arranged.

P-type thermoelectric conversion element 350P and N-type thermoelectric conversion element 350N are mounted on wiring substrate 360, respectively. Specifically, P-type thermoelectric conversion element 350P and N-type thermoelectric conversion element 350N are solder-bonded to wiring 365 of electrical wiring substrate 360 through plated metal layers (320P and 320N) formed on both ends of thermoelectric conversion materials (300P and 300N), respectively. In addition, wiring 365 of electrical wiring substrate 360 electrically connects P-type thermoelectric conversion element 350P and N-type thermoelectric conversion element 350N in series.

On the other hand, similarly to the thermoelectric conversion module shown in FIG. 5A, the thermoelectric conversion module shown in FIG. 5B includes P-type thermoelectric conversion element and N-type thermoelectric conversion element. However, the thermoelectric conversion module shown in FIG. 5B is different from the thermoelectric conversion module shown in FIG. 5A in that tube 310 (310P or 310N) is filled with thermoelectric conversion material 300 (300P and 300N). That is, thermoelectric conversion element 350P′ in FIG. 5B includes tube (for example, glass tube) 310P, P-type thermoelectric conversion material 300P with which tube 310P is filled, and plated metal layers 320P that are formed on both ends of P-type thermoelectric conversion material 300P. Similarly, N-type thermoelectric conversion element 350N′ includes tube (for example, glass tube) 310N, N-type thermoelectric conversion material 300N with which tube 310N is filled, and plated metal layers 320N formed on both ends of N-type thermoelectric conversion material 300N. That is, thermoelectric conversion element 350′ shown in FIG. 4B is arranged.

In the thermoelectric conversion module shown in FIG. 5B, thermoelectric conversion element 350P′ and thermoelectric conversion element 350N′ are disposed in a close contact manner. Specifically, tubes 310 (310P and 310N) of a plurality of the thermoelectric conversion elements 350′ come into contact with each other. In thermoelectric conversion elements 350′, insulating tubes 310 is filled with thermoelectric conversion material 300, even when thermoelectric conversion elements 350′ come into contact with each other, a short-circuit does not occur. Accordingly, as shown in FIG. 5B, thermoelectric conversion elements 350′ may be disposed in a close contact manner, and thus arrangement may be carried out with high density. As a result, a power generation amount per unit area of the thermoelectric conversion module can be increased.

On the other hand, in the thermoelectric conversion module shown in FIG. 5A, it is necessary for thermoelectric conversion elements 350P and 350N to be sufficiently separated from each other so as to prevent these from coming into contact with each other. Therefore, it is difficult to arrange thermoelectric conversion element 350 with high density, and thus the power generation amount per unit area of the thermoelectric conversion module may be decreased.

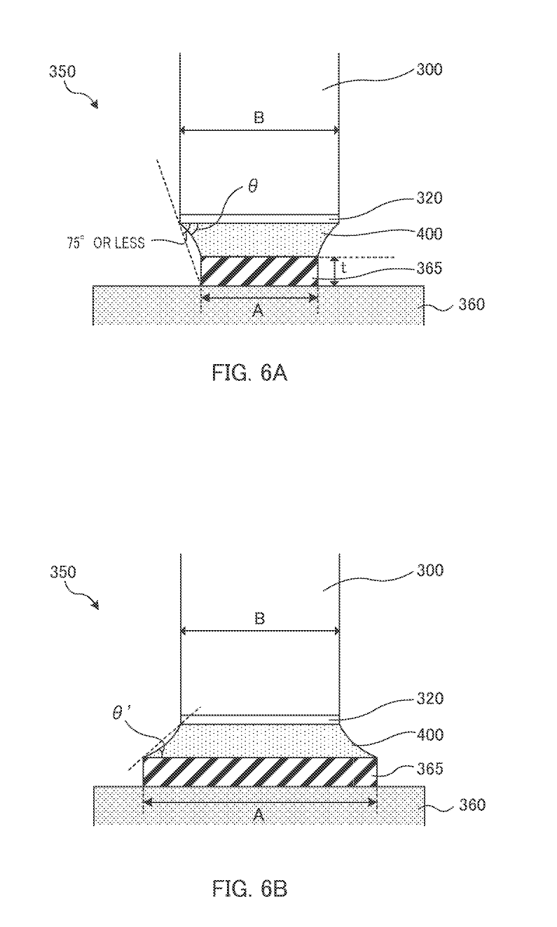

When thermoelectric conversion element 350 of the thermoelectric conversion module shown in FIG. 5A is mounted on electrical wiring plate 360, an example of a bonding portion (corresponding to a Z portion in FIG. 5A) state is shown in FIGS. 6A and 6B. That is, FIGS. 6A and 6B are cross-sectional diagrams taken along a line Y-Y in FIG. 3. That is, FIGS. 6A and 6B are cross-sectional diagrams along a direction orthogonal to an electrical connection direction between thermoelectric conversion elements.

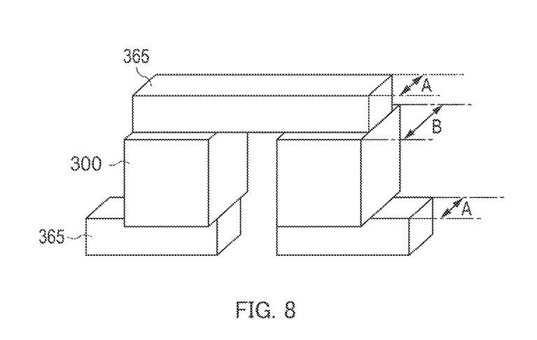

In addition, FIG. 8 shows a perspective diagram illustrating a connection portion between thermoelectric conversion element 350 shown in FIG. 6A and electrical wiring 365 that is connected to both ends of thermoelectric conversion element 350.

FIGS. 6A and 8 illustrate a case where width A of wiring 365 of electrical wiring plate 360 is narrower than width B of thermoelectric conversion material 300 of thermoelectric conversion element 350, and FIG. 6B illustrates a case where the width of wiring 365 of electrical wiring plate 360 is wider than the width of thermoelectric conversion material 300 of thermoelectric conversion element 350. Width A represents the longest width of a solder-bonding surface of wiring 365. Width B represents the longest width of a solder-bonding surface (commonly, a surface of a plated metal layer) of the thermoelectric conversion element.

Even in a solder-bonded state shown in FIG. 6A or a solder-bonded state shown in FIG. 6B, solder 400 has a fillet shape, and thus connection reliability between thermoelectric conversion element 350 and wiring 365 by solder is high. The fillet shape represents a spread bottom shape.

It is preferable that a contact angle θ of solder 400 with respect to plated metal layer 320 in FIG. 6A be 75° or less, and more preferably be in a range of 15° to 45°. The contact angle θ may be adjusted by adjusting width B of thermoelectric conversion material 300 and width A of wiring 365 of electrical wiring plate 360. For example, as shown in FIG. 6A, when an intersection angle between a line connecting an edge of plated metal layer 320 of thermoelectric conversion material 300 with an edge of wiring 365, and the solder-bonding surface of plated metal layer 320 is set to 75° or less, the contact angle θ becomes 75° or less.

As an example, width B of thermoelectric conversion material 300 of thermoelectric conversion element 350 and width A of wiring 365 of electrical wiring plate 360 in FIG. 6A satisfy an expression of A≦B−2t/tan 75°. Here, t represents a thickness of the wiring. In addition, a thickness of the solder is set to be sufficiently small.

It is preferable that a contact angle θ′ of solder 400 with respect to wiring 365 in FIG. 6B be 75° or less, and more preferably a range of 15° to 45°. The contact angle θ′ may be adjusted by adjusting width B of thermoelectric conversion material 300 and width A of wiring 365 of electrical wiring plate 360. For example, as shown in FIG. 6B, when an intersection angle between a line connecting an edge of plated metal layer 320 of thermoelectric conversion material 300 with an edge of wiring 365, and the solder-bonding surface of wiring 365 is set to 75° or less, the contact angle θ′ becomes 75° or less.

As described above, when width B of thermoelectric conversion material 300 and width A of wiring 365 of electrical wiring plate 360 are made different from each other, a shape of the solder is set to a fillet shape, and thus bonding strength may be increased. Particularly, similarly to a solder-bonding state shown in FIG. 6A, when width A of wiring 365 of electrical wiring plate 360 is made smaller than width B of thermoelectric conversion material 300 of thermoelectric conversion element 350, an area necessary for mounting becomes small. Accordingly, the mounting density of the thermoelectric conversion element increases, and thus a power generation amount per unit area may be increased.

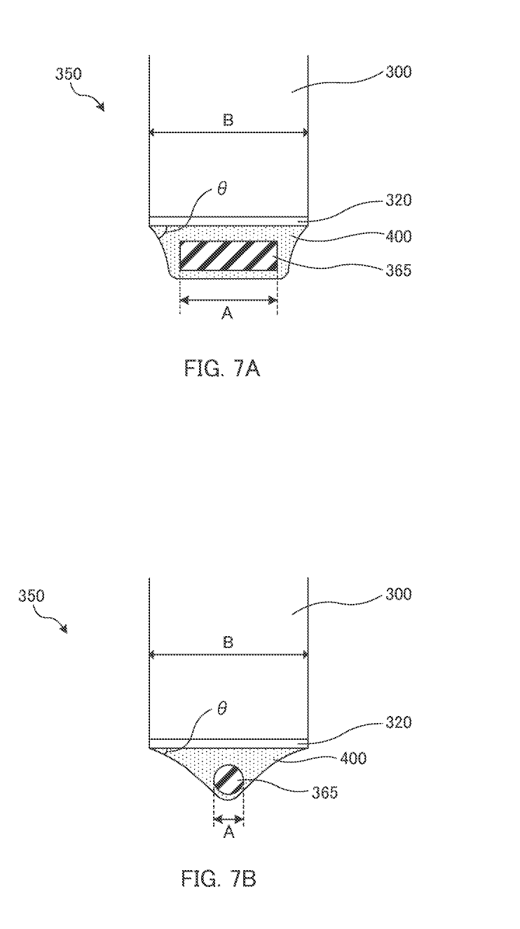

Similarly to FIGS. 6A and 6B, FIGS. 7A and 7B illustrate an example of a bonding portion when thermoelectric conversion element 350 is mounted on electrical wiring plate 360 in the thermoelectric conversion module. However, FIGS. 7A and 7B illustrate a state in which thermoelectric conversion element 350 is solder-bonded to electrical wiring 365 constituted by an electrical wire. That is, electrical wiring 365 does not come into contact with electrical wiring plate 360.

Electrical wiring 365 in FIG. 7A is a flat electrical wire, and electrical wiring 365 in FIG. 7B is an electrical wire having a circular cross-section. In FIGS. 7A and 7B, width A of electrical wiring 365 constituted by an electrical wire is smaller than width B of thermoelectric conversion material of thermoelectric conversion element 350. Accordingly, solder 400 has a fillet shape, and thus strong solder-bonding is carried out. Contact angle θ of solder 400 with respect to a solder-bonding surface of plated metal layer 320 is 75° or less. In addition, an area necessary to bond thermoelectric conversion element 350 is small, and thus the mounting density of the thermoelectric conversion element increases. As a result, a power generation amount per unit area may be increased.

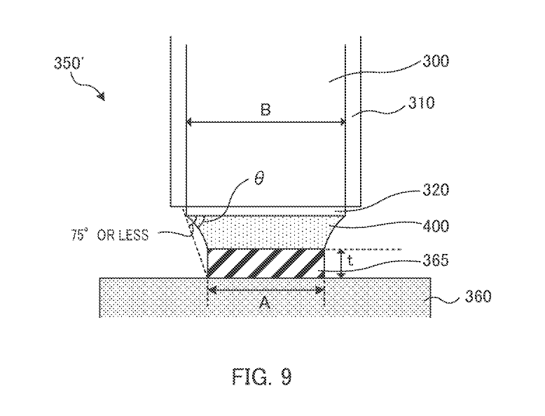

FIG. 9 illustrates an example of a bonding portion state when mounting thermoelectric conversion element 350′ (350P′ or 350N′) shown in FIG. 5B on electrical wiring plate 360. As shown in FIG. 9, width A of wiring 365 of electrical wiring plate 360 is smaller than width B of thermoelectric conversion material 300 of thermoelectric conversion element 350′. Accordingly, solder 400 has a fillet shape, and thus the mounting density may be improved.

Furthermore, in FIG. 9, when width A is made smaller than width B, in a case of solder-bonding thermoelectric conversion element 350′ to wiring 365, contact between solder 400 and tube 310 may be suppressed. On the other hand, when width A is larger than width B, there is a tendency for solder 400 and tube 310 to come into contact with each other during the welding thereof. Tube 310 has low wettability with respect to the solder, and thus when solder 400 and tube 310 come into contact with each other, it is difficult for the shape of solder 400 to be a fillet shape, and solder 400 comes into contact with both of wiring 365 and tube 310. Therefore, there is a tendency for a thermal migration between wiring 365 and tube 310 to occur, and thus the power generation efficiency of the thermoelectric conversion module decreases.

As shown in FIG. 6A, and FIG. 7A to FIG. 9, in the thermoelectric conversion module of the invention, it is preferable that the width of the wiring of the electrical wiring plate be smaller than the width of the thermoelectric conversion material of the thermoelectric conversion element. Here, wiring 365 is located at a central portion in a width direction of the end surface of thermoelectric conversion material 300 of the thermoelectric conversion element. That is, wiring 365 is disposed not to lead out from an edge of the end surface in the width direction of thermoelectric conversion material 300 of the thermoelectric conversion element. This is because solder 400 is made to have an appropriate fillet shape.

### INDUSTRIAL APPLICABILITY

In the thermoelectric conversion module of the invention, connection reliability between the thermoelectric conversion element and the electrical wiring plate that electrically connects the thermoelectric conversion elements is high. Accordingly, the thermoelectric conversion module of the invention has high long-term reliability.

### REFERENCE SIGNS LIST

15, 15′ Current introduction terminal
50 P-type thermoelectric conversion element
60 N-type thermoelectric conversion element
70 Bonding electrode
80 Ceramic substrate
90 Ceramic substrate
100 Thermoelectric conversion module
110 Honeycomb mold
120 Insulating resin
130 Block
130′ Block piece
140 Cutter
150 P-type thermoelectric conversion material
151 P-type thermoelectric conversion element
160 N-type thermoelectric conversion material
161 N-type thermoelectric conversion element
300 Thermoelectric conversion material
300P P-type thermoelectric conversion material
300N N-type thermoelectric conversion material
310, 310P, 310N Tube
320, 320P, 320N Plated metal layer
350, 350′ Thermoelectric conversion element
350P, 350P′ P-type thermoelectric conversion element
350N, 350N′ N-type thermoelectric conversion element
360 Electrical wiring plate
365 Wiring
400 Solder
A Width of wiring of electrical wiring plate
B Width of thermoelectric conversion material
θ, θ′ Contact angle

1. A thermoelectric conversion module comprising:
two or more P-type thermoelectric conversion elements that include a P-type thermoelectric conversion material;
two or more N-type thermoelectric conversion elements that include an N-type thermoelectric conversion material; and
an electrical wiring that connects each of the P-type thermoelectric conversion elements with each of the N-type thermoelectric conversion elements in series,
wherein the electrical wiring is solder-bonded to a longitudinal end surface of the P-type thermoelectric conversion material and the N-type thermoelectric conversion material,
a width of the electric wiring is narrower than a width of the P-type thermoelectric conversion material and the N-type thermoelectric conversion material,
the electrical wiring is located at a central portion in the width direction of the end surface, and
a solder that bonds each of the end surfaces and the electrical wiring has a fillet shape.

2. The thermoelectric conversion module according to claim 1,
wherein the two or more P-type thermoelectric conversion elements, and the two or more N-type thermoelectric conversion elements including the N-type thermoelectric conversion material are arranged along a plurality of rows.

3. The thermoelectric conversion module according to claim 1,
wherein a contact angle of the solder that solder-bonds the electrical wiring with respect to the end surfaces of the P-type thermoelectric conversion element or the N-type thermoelectric conversion element is 75° or less.

4. The thermoelectric conversion module according to claim 1,
wherein the P-type thermoelectric conversion element includes a plated metal layer that covers the longitudinal end surfaces of the P-type thermoelectric conversion material, and the electrical wiring is solder-bonded to the P-type thermoelectric conversion material through the plated metal layer, and
the N-type thermoelectric conversion element includes a plated metal layer that covers the longitudinal end surfaces of the N-type thermoelectric conversion material, and the electrical wiring is solder-bonded to the N-type thermoelectric conversion material through the plated metal layer.

5. The thermoelectric conversion module according to claim 1,
wherein the P-type thermoelectric conversion element further includes an insulating tube which is filled with the P-type thermoelectric conversion material, and
the N-type thermoelectric conversion element further includes an insulating tube which is filled with the N-type thermoelectric conversion material.
